(19) United States
(12) Patent Application Publication
(10) Pub. No.: US 2015/0317204 A1
(43) Pub. Date: Nov. 5, 2015

(54) Systems and Methods for Efficient Data Refresh in a Storage Device

(71) Applicant: LSI Corporation, San Jose, CA (US)

(72) Inventor: Shaohua Yang, San Jose, CA (US)

(73) Assignee: LSI Corporation, San Jose, CA (US)

(21) Appl. No.: 14/283,170

(22) Filed: May 20, 2014

Related U.S. Application Data
(60) Provisional application No. 61/986,605, filed on Apr. 30, 2014.

(51) Int. Cl. G06F 11/10; H03M 13/11; G11C 29/52; G11C 11/406

(52) U.S. Cl. CPC G06F 11/1068; G11C 11/406; H03M 13/1102; G11C 29/52

(57) ABSTRACT

Systems and method relating generally to data storage processing, and more particularly to systems and methods for refreshing data in a data storage device.

### CROSS REFERENCE TO RELATED APPLICATIONS

The present application claims priority to (is a non-provisional of) U.S. Pat. App. No. 61/986,605 entitled “Systems and Methods for Efficient Data Refresh in a Storage Device”, and filed Apr. 30, 3014 by Yang et al. The entirety of the aforementioned provisional patent application is incorporated herein by reference for all purposes.

### FIELD OF THE INVENTION

Systems and method relating generally to data storage processing, and more particularly to systems and methods for refreshing data in a data storage device.

### BACKGROUND

A storage medium may include a number of tracks written with data. Writing data to one track results in a degradation of the data on an adjacent track. As different tracks are written at a different frequency, one track may be written a number of times before the adjacent track is re-written. In such a case, the degradation to the adjacent track increases and at some point results in a lack of readability of the adjacent track. Without re-writing the track, the degradation will continue until the data is no longer recoverable. This and other reasons exist that demand the re-writing of data previously stored to the storage medium back to that storage medium.

Hence, for at least the aforementioned reasons, there exists a need in the art for advanced systems and methods for decoding encoded data sets.

### SUMMARY

Systems and method relating generally to data storage processing, and more particularly to systems and methods for refreshing data in a data storage device.

Various embodiments of the present invention provide data storage systems that include a data processing circuit and a data write circuit. The data processing circuit is operable to: receive a pre-processed encoded data set derived from a location on a storage medium; apply a data processing algorithm to the pre-processed encoded data set to recover the original encoded data set that includes user data and encoding information; and provide the user data to a requesting device. The data write circuit is operable to re-write the recovered original encoded data set to the storage medium.

This summary provides only a general outline of some embodiments of the invention.

The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a solid state storage device including efficient refresh circuitry in accordance with various embodiments of the present invention;

FIG. 2 shows a storage system including efficient refresh circuitry in accordance with various embodiments of the present invention;

FIG. 3 shows a data write circuit including a data encoder circuit and selectable refresh circuitry in accordance with various embodiments of the present invention;

FIG. 4 is a data processing system including a data decoding circuit and refresh selection circuitry in accordance with various embodiments of the present invention; and

FIG. 5 is a flow diagram showing a method for data processing that includes selectable data re-writing in accordance with some embodiments of the present invention.

### DETAILED DESCRIPTION OF SOME EMBODIMENTS

Systems and method relating generally to data storage processing, and more particularly to systems and methods for refreshing data in a data storage device.

Various embodiments of the present invention provide data storage systems that include a data processing circuit and a data write circuit. The data processing circuit is operable to: receive a pre-processed encoded data set derived from a location on a storage medium; apply a data processing algorithm to the pre-processed encoded data set to recover the original encoded data set that includes user data and encoding information; and provide the user data to a requesting device. The data write circuit is operable to re-write the recovered original encoded data set to the storage medium.

In some instances of the aforementioned embodiments, the data write circuit further includes a data encoding circuit operable to encode the user data to yield the original encoded data set. The data write circuit is further operable to initially write the original encoded data set to the storage medium. In some cases, the data encoding circuit applies a low density parity check encoding algorithm. In various cases, the data processing circuit further includes a refresh determination circuit operable to determine that a refresh of the pre-processed encoded data is warranted. In such cases, the data write circuit may further include a selector circuit operable to select the recovered original encoded data set provided from the data processing circuit as a write data output when it is determined that a refresh of the pre-processed encoded data is warranted. The refresh determination circuit is operable to determine that a refresh of the pre-processed encoded data is warranted based upon a condition. The condition may be, but is not limited to, exceeding a defined number of reads of the pre-processed encoded data since a last write of the pre-processed encoded data; exceeding a defined time period since the last write of the pre-processed encoded data; exceeding a defined level of inter-cell interference evident in the pre-processed encoded data; exceeding a defined level of adjacent track interference evident in the pre-processed encoded data; and/or exceeding a number of iterations of a data decoding algorithm required to yield the original encoded data set. In various cases, upon determination that a refresh of the pre-processed encoded data is warranted, data encoding circuit does not re-encode the user data to yield the original encoded data set.

In some instances of the aforementioned embodiments, the data processing algorithm includes a low density parity check decoding algorithm. The storage medium may be, but is not limited to, a solid state storage medium, a magnetic storage medium, and an optical storage medium. In particular cases, the data storage system is implemented as part of an integrated circuit.

Other embodiments of the present invention provide methods for data refresh in a storage device. The methods include: writing an original encoded data set to a storage medium where the original encoded data set includes user data and encoding information; accessing a pre-processed encoded data set from a storage medium; applying a data decoding algorithm to the pre-processed encoded data set to recover the original encoded data set; providing the user data to a requesting device; and re-writing the recovered original encoded data set to the storage medium.

In some cases, the methods further include encoding the user data to yield the original encoded data set. In some cases, encoding the user data set includes applying a low density parity check encoding algorithm to the user data. In various cases the methods further include: determining that a refresh of the pre-processed encoded data is warranted; and selecting the recovered original encoded data set as a write data output when it is determined that a refresh of the pre-processed encoded data is warranted.

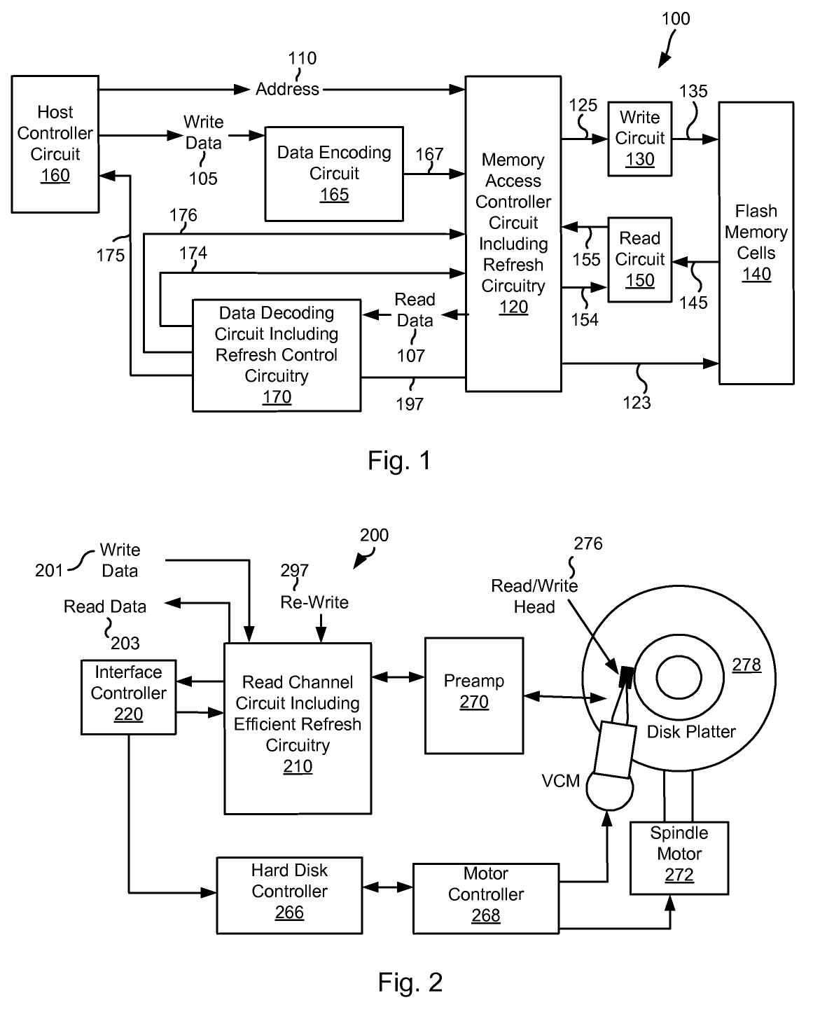

Turning to FIG. 1, a solid state storage device 100 including efficient refresh circuitry in accordance with various embodiments of the present invention. The efficient refresh circuitry includes a data decoding circuit including refresh control circuitry 170 and a memory access controller circuit including refresh circuitry 120. Storage device 100 additionally includes a host controller circuit 160 that directs read and write access to flash memory cells 140. Flash memory cells 140 may be NAND flash memory cells or another type of solid state memory cells as are known in the art.

A data write is effectuated when host controller circuit 160 provides write data 105 to be written along with an address 110 indicating the location to be written. A data encoding circuit 165 applies a data encoding algorithm to the received write data 105 to yield an encoded output 167. Encoded output 167 may include write data 105 along with some additional parity data. In one particular embodiment of the present invention, the data encoding algorithm may be a low density parity check algorithm as is known in the art. Based on the disclosure provided herein, one of ordinary skill in the art will recognize a variety of data encoding algorithms that may be used in relation to different embodiments of the present invention. Encoded output 167 is provided to memory access controller 120.

A memory access controller 120 formats encoded output 167 as encoded write data 125, and generates a physical address 123 that corresponds to address 110. Encoded write data 125 is provided to a write circuit 130. Write circuit 130 provides a write voltage 135 corresponding to respective groupings of encoded write data 125 that is used to charge respective flash memory cells addressed by address 123. For example, where flash memory cells are two bit cells (i.e., depending upon the read voltage, a value of ‘11’, ‘10’, ‘00’, or ‘01’ is returned), the following voltages may be applied to store the data:

| Two Bit Data Input | Voltage Output |
|---|---|
| ‘11’ | V3 |
| ‘10’ | V2 |
| ‘00’ | V1 |
| ‘01’ | V0 |

Where V3 is greater than V2, V2 is greater than V1, and V1 is greater than V0. It should be noted that the aforementioned table is merely an example, and that different devices may assign different bit values to the different voltage thresholds. For example in other cases the values in the following table may be used:

| Two Bit Data Input | Voltage Output |
|---|---|
| ‘01’ | V3 |
| ‘00’ | V2 |
| ‘10’ | V1 |
| ‘11’ | V0 |

Of course, other bit patterns may be assigned to different thresholds. Also, it should be noted that while a flash memory having two bits per cell is shown, single bit flash memories or flash memories having three or more bits per cell are possible in accordance with different embodiments of the present invention.

A data read is effectuated when host controller circuit 160 provides address 110 along with a request to read data from the corresponding location in flash memory cells 140. Memory access controller 120 generates a physical address corresponding to address 110 and provides the physical address as address 123. A voltage 145 from a location indicated by address 123 is returned from flash memory cells 140 to a read circuit 150. Read circuit 150 compares the voltage to a number of threshold values 154 to reduce the voltage to a multi-bit read data 155. Using the same two bit example, the following multi-bit read data 155 results:

| Voltage Input | Two Bit Data Output |
|---|---|
| >V2 | ‘11’ |
| >V1 | ‘10’ |
| >V0 | ‘00’ |
| <=V0 | ‘01’ |

This multi-bit read data 155 is provided from memory access controller 120 to data decoding circuit 170 as read data 107. Data decoding circuit 170 applies a data decoding algorithm to read data 107 using soft data 173 that is either accessed or generated by memory access controller circuit 120. Soft data may either be provided from flash memory cells 140 where such are available, or may be generated by memory access controller circuit 120. Such generation of soft information may be done using any approach known in the art for generating soft data. As one example, generation of soft information may be done similar to that disclosed in U.S. patent application Ser. No. 14/047,423 entitled “Systems and Methods for Enhanced Data Recovery in a Solid State Memory System”, and filed by Xia et al. on Oct. 7, 2013. The entirety of the aforementioned application was previously incorporated herein by reference for all purposes.

Data decoding circuit 170 applies a data decoding algorithm to read data 107 and soft data 174 to yield a decoded output. This may include an iterative application of the same data decoding algorithm to read data 107. Where the decoded output converges (i.e., results in a correction of all remaining errors in read data 107), the decoded output is stripped of all parity information leaving only original user data 175 earlier stored at the direction of host controller circuit 160. This original user data 175 is provided to host controller 160. Alternatively, where the decoded output fails to converge (i.e., errors remain in the decoded output), another iteration of the data decoding algorithm may be applied to read data 107 guided by the previous decoded output to yield an updated decoded output. This process continues until either the data decoding algorithm converges or a timeout condition is reached.

Data decoding circuit 170 receives a re-write signal 197 that when asserted causes data accessed from flash memory cells 140 to be re-written back to flash memory cells. This re-write process refreshes the data stored in the flash memory cells which has a tendency to degrade as a function of both time and a number of reads. In one embodiment of the present invention, memory access controller circuit 120 asserts re-write signal 197 when currently read data has not been refreshed for a defined period, or when currently read data has not been refreshed for a defined number of read accesses.

In addition, data decoding circuit 170 asserts an internal re-write signal when there is an indication other than the assertion of re-write signal 197 that a data refresh may be beneficial. For example, data decoding circuit 170 may assert the internal re-write signal when data decoding is required more than a defined number of iterations, or when more than a defined level of inter-cell interference is detected. When either the internal re-write signal or re-write signal 197 is asserted, data decoding circuit 170 asserts a refresh signal 174 and provides the decoded output prior to stripping all parity information as write back data 176. Write back data 176 is the same as encoded data 167 that was originally provided to memory access controller circuit 120 from data encoding circuit 165.

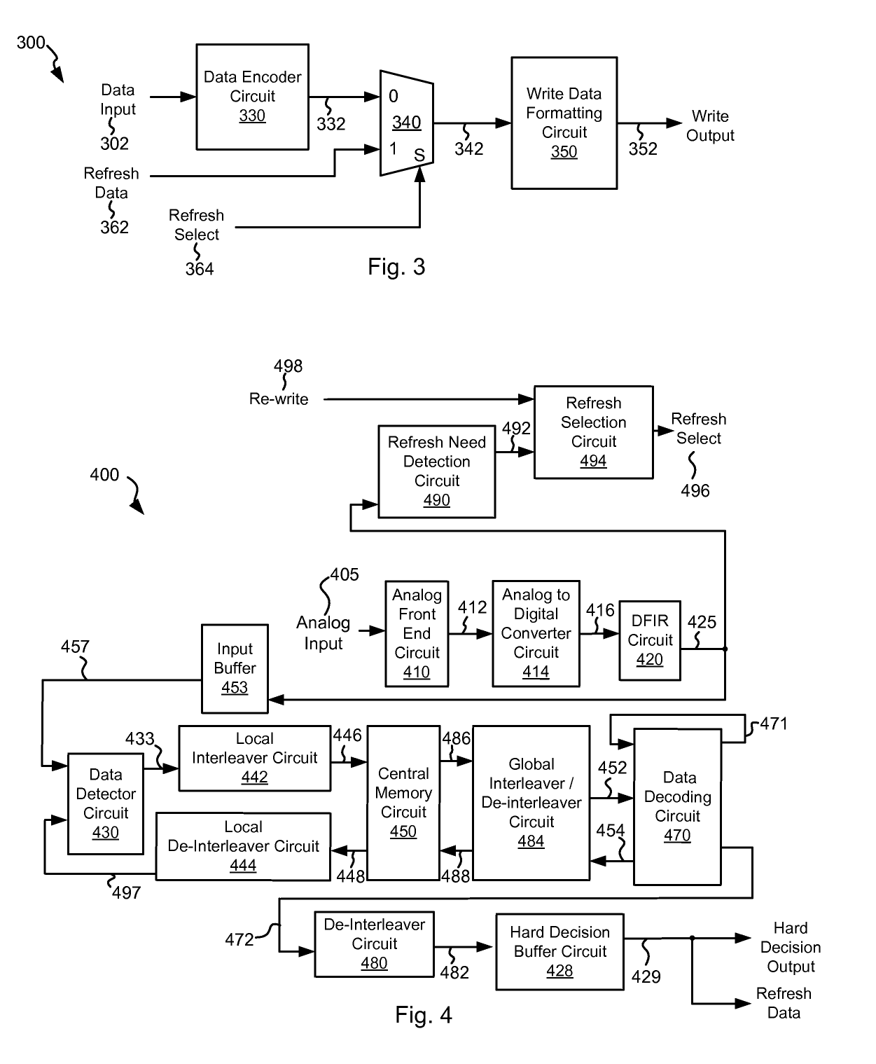

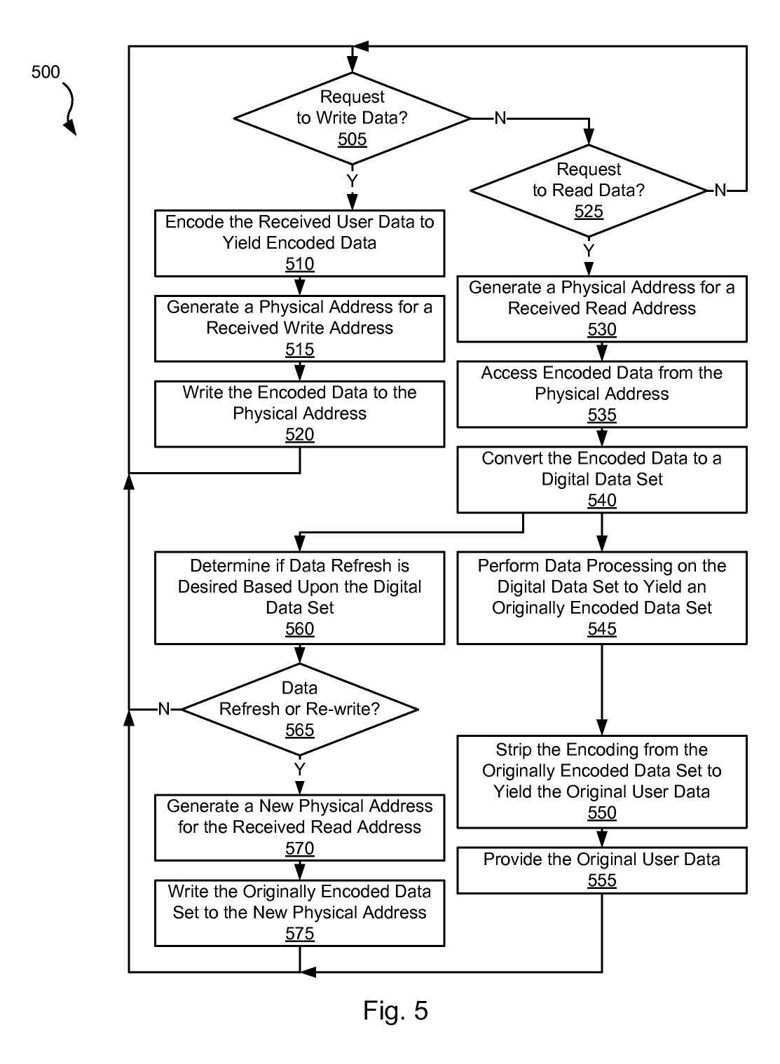

When refresh signal 174 is asserted, memory access controller circuit 120 generates a new physical address corresponding to address 110, and causes write back data 176 to be stored to flash memory cells 140 at the location indicated by the newly generated physical address which is provided as physical address 123. By doing this, data may be refreshed to flash memory cells 140 without requiring re-encoding by data encoding circuit 165. Avoiding re-encoding results in power savings and a reduction in latency for the refresh process. Data encoding circuit 165, the refresh control circuitry of memory access controller circuit 120, and write circuit 130 may be implemented similar to that discussed below in relation to FIG. 3. The refresh control circuitry included in data decoding circuit 170 may be similar to the refresh control circuitry included in the circuit discussed below in relation to FIG. 4. The refresh process may be done similar to that discussed below in relation to FIG. 5.

Turning to FIG. 2, a storage system 200 including a read channel circuit 210 having efficient refresh circuitry is shown in accordance with various embodiments of the present invention. Storage system 200 may be, for example, a hard disk drive. Storage system 200 also includes a preamplifier 270, an interface controller 220, a hard disk controller 266, a motor controller 268, a spindle motor 272, a disk platter 278, and a read/write head 276. Interface controller 220 controls addressing and timing of data to/from disk platter 278. The data on disk platter 278 consists of groups of magnetic signals that may be detected by read/write head assembly 276 when the assembly is properly positioned over disk platter 278. In one embodiment, disk platter 278 includes magnetic signals recorded in accordance with either a longitudinal or a perpendicular recording scheme.

A data decoder circuit used in relation to read channel circuit 210 may be, but is not limited to, a low density parity check (LDPC) decoder circuit as are known in the art. Such low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

In a typical read operation, read/write head assembly 276 is accurately positioned by motor controller 268 over a desired data track on disk platter 278. Motor controller 268 both positions read/write head assembly 276 in relation to disk platter 278 and drives spindle motor 272 by moving read/write head assembly to the proper data track on disk platter 278 under the direction of hard disk controller 266. Spindle motor 272 spins disk platter 278 at a determined spin rate (RPMs). Once read/write head assembly 276 is positioned adjacent the proper data track, magnetic signals representing data on disk platter 278 are sensed by read/write head assembly 276 as disk platter 278 is rotated by spindle motor 272. The sensed magnetic signals are provided as a continuous, minute analog signal representative of the magnetic data on disk platter 278. This minute analog signal is transferred from read/write head assembly 276 to read channel circuit 210 via preamplifier 270. Preamplifier 270 is operable to amplify the minute analog signals accessed from disk platter 278. In turn, read channel circuit 210 decodes and digitizes the received analog signal to recreate the information originally written to disk platter 278. This data is provided as read data 203 to a receiving circuit. A write operation is substantially the opposite of the preceding read operation with write data 201 being provided to read channel circuit 210. This data is then encoded and written to disk platter 278.

As part of processing the received information, read channel circuit 210 may utilize a data processing circuit that includes both a data detection circuit and a data decode circuit. In some cases, multiple iterations through the data decoder circuit (i.e., local iterations) for each pass through both the data detection circuit and the data decoder circuit (i.e., global iterations). A data write is effectuated when write data 201 is provided to read channel circuit 210 along with a physical address from interface controller 220 indicating the location of disk platter 278 to which the data is to be written. A data encoding circuit included as part of read channel circuit 210 applies a data encoding algorithm to the received write data 201 to yield an encoded output. The encoded output may include write data 201 along with some additional parity data. In one particular embodiment of the present invention, the data encoding algorithm may be a low density parity check algorithm as is known in the art. Based on the disclosure provided herein, one of ordinary skill in the art will recognize a variety of data encoding algorithms that may be used in relation to different embodiments of the present invention. The encoded output is provided to a write controller that formats the data in preparation for writing the data to disk platter 278 via preamplifier 270.

A data read is effectuated when a read request is received via interface controller 220 along a physical address from interface controller 220 indicating the location of disk platter 278 from which the data is to be read. Data from the identified address is accessed from disk platter 278 and provided to read channel circuit 210 via preamplifier 270. A data decoding circuit included as part of read channel circuit 210 applies a data decoding algorithm to the read data received from disk platter 278 to yield a decoded output. This may include an iterative application of the same data decoding algorithm to the received data. Where the decoded output converges (i.e., results in a correction of all remaining errors in the received data), the decoded output is stripped of all parity information leaving only original user data that was earlier stored at the direction of interface controller 220. This original user data is provided as read data 203. Alternatively, where the decoded output fails to converge (i.e., errors remain in the decoded output), another iteration of the data decoding algorithm may be applied to the received data guided by the previous decoded output to yield an updated decoded output. This process continues until either the data decoding algorithm converges or a timeout condition is reached.

Read channel circuit 210 receives a re-write signal 297 that when asserted causes data accessed from disk platter 278 to be re-written back to disk platter 278. This re-write process refreshes the data stored in disk platter 278 which has a tendency to degrade as a function of both time and a number of writes to adjacent tracks. In one embodiment of the present invention, a controller (not shown) asserts re-write signal 297 when currently read data has not been refreshed for a defined period.

In addition, read channel circuit 210 asserts an internal re-write signal when there is an indication other than the assertion of re-write signal 297 that a data refresh may be beneficial. For example, read channel circuit 210 may assert the internal re-write signal when data decoding is required more than a defined number of iterations, or when more than a defined level of adjacent track interference is detected. When either the internal re-write signal or re-write signal 297 is asserted, read channel circuit 210 causes the decoded output prior to stripping all parity information to be written back to disk platter 278. The write back data is the same as the encoded data that was originally stored to disk platter 278. By doing this, data may be refreshed to disk platter 278 without requiring re-encoding by the encoder circuit of read channel circuit 210. Avoiding re-encoding results in power savings and a reduction in latency for the refresh process. A combination of a data encoding circuit, a refresh control circuit, and a write controller that may be implemented as part of read channel circuit is discussed below in relation to FIG. 3. A refresh control circuit that may be implemented as part of read channel circuit 210 is discussed below in relation to FIG. 4. The refresh process may be done similar to that discussed below in relation to FIG. 5.

Turning to FIG. 3, a data write circuit 300 including a data encoder circuit 330 and selectable refresh circuitry is shown in accordance with various embodiments of the present invention. Data encoder circuit 330 applies a data encoding algorithm to a received data input 302 to yield an encoded output 332. Data input 302 is user data that is to be stored, and encoded output 332 includes the user data received as data input 302 and parity data generated by data encoder circuit 330. In some embodiments of the present invention, the data encoding algorithm is a low density parity check encoding algorithm. Based upon the disclosure provided herein, one of ordinary skill in the art will recognize a variety of data encoding algorithms that may be used in relation to different embodiments of the present invention.

Data write circuit 300 additionally includes a selector circuit 340 that selects one of a refresh data 362 or encoded output 332 as a selected write data set 342 based upon a refresh select input 364. Refresh data 362 is received from a data processing circuit that is processing read data. Refresh data 362 is the same as encoded data 332 that was previously stored and is now being read. Refresh select signal 364 is asserted when either a re-write input (not shown) is asserted indicating currently read data is to be refreshed to the storage medium, or where it is determined that a data refresh would reduce interference detected in the read data. As such, currently read data is selected as selected write data set 342. Such an approach allows for refreshing data to the storage medium without requiring re-encoding by data encoder circuit 330. Avoiding re-encoding results in power savings and a reduction in latency for the refresh process.

Selected write data set 342 is provided to a write data formatting circuit 350. Write formatting circuit 350 may be any circuit known in the art that is capable of preparing a data set for storage to a storage medium. In one particular embodiment of the present invention, write data formatting circuit 350 includes a write pre-compensation circuit that may be any circuit known in the art that is capable of modifying or arranging selected write data set 342 in a format and/or domain suitable for transfer via a transfer medium (not shown). Such a transfer medium may be, but is not limited to, a storage medium or a communication medium. In addition, write data formatting circuit 350 includes a write driver circuit that generates a write output 352 from the aforementioned write pre-compensation circuit. The write driver circuit may be any circuit capable of providing the received information to the storage medium. As such, the write driver circuit may be, but is not limited to, a solid state storage device write circuit, or a magnetic storage device write circuit.

Turning to FIG. 4, a data processing system 400 includes a data decoding circuit 470 and refresh selection circuitry in accordance with various embodiments of the present invention. Data processing system 400 includes an analog front end circuit 410 that receives an analog signal 405. Analog front end circuit 410 processes analog signal 405 and provides a processed analog signal 412 to an analog to digital converter circuit 414. Analog front end circuit 410 may include, but is not limited to, an analog filter and an amplifier circuit as are known in the art. Based upon the disclosure provided herein, one of ordinary skill in the art will recognize a variety of circuitry that may be included as part of analog front end circuit 410. In some cases, analog signal 405 is derived from a read/write head assembly (not shown) that is disposed in relation to a storage medium (not shown). In other cases, analog signal 405 is derived from a receiver circuit (not shown) that is operable to receive a signal from a transmission medium (not shown). The transmission medium may be wired or wireless. Based upon the disclosure provided herein, one of ordinary skill in the art will recognize a variety of source from which analog input 405 may be derived.

Analog to digital converter circuit 414 converts processed analog signal 412 into a corresponding series of digital samples 416. Analog to digital converter circuit 414 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 416 are provided to an equalizer circuit 420. Equalizer circuit 420 applies an equalization algorithm to digital samples 416 to yield an equalized output 425. In some embodiments of the present invention, equalizer circuit 420 is a digital finite impulse response filter circuit as are known in the art. It may be possible that equalized output 425 may be received directly from a storage device in, for example, a solid state storage system. In such cases, analog front end circuit 410, analog to digital converter circuit 414 and equalizer circuit 420 may be eliminated where the data is received as a digital data input. Equalized output 425 is stored to an input buffer 453 that includes sufficient memory to maintain a number of codewords (i.e., encoded data sets) until processing of that codeword is completed through a data detector circuit 430 and three step data decoding circuit 470 including, where warranted, multiple global iterations (passes through both data detector circuit 430 and three step data decoding circuit 470) and/or local iterations (passes through three step data decoding circuit 470 during a given global iteration). An output 457 is provided to data detector circuit 430.

Data detector circuit 430 may be a single data detector circuit or may be two or more data detector circuits operating in parallel on different codewords. Whether it is a single data detector circuit or a number of data detector circuits operating in parallel, data detector circuit 430 is operable to apply a data detection algorithm to a received codeword or data set. In some embodiments of the present invention, data detector circuit 430 is a Viterbi algorithm data detector circuit as are known in the art. In other embodiments of the present invention, data detector circuit 430 is a maximum a posteriori data detector circuit as are known in the art. Of note, the general phrases “Viterbi data detection algorithm” or “Viterbi algorithm data detector circuit” are used in their broadest sense to mean any Viterbi detection algorithm or Viterbi algorithm detector circuit or variations thereof including, but not limited to, bi-direction Viterbi detection algorithm or bi-direction Viterbi algorithm detector circuit. Also, the general phrases “maximum a posteriori data detection algorithm” or “maximum a posteriori data detector circuit” are used in their broadest sense to mean any maximum a posteriori detection algorithm or detector circuit or variations thereof including, but not limited to, simplified maximum a posteriori data detection algorithm and a max-log maximum a posteriori data detection algorithm, or corresponding detector circuits. Based upon the disclosure provided herein, one of ordinary skill in the art will recognize a variety of data detector circuits that may be used in relation to different embodiments of the present invention. In some cases, one data detector circuit included in data detector circuit 430 is used to apply the data detection algorithm to the received codeword for a first global iteration applied to the received codeword, and another data detector circuit included in data detector circuit 430 is operable apply the data detection algorithm to the received codeword guided by a decoded output accessed from a central memory circuit 450 on subsequent global iterations.

Upon completion of application of the data detection algorithm to the received codeword on the first global iteration, data detector circuit 430 provides a detector output 433. Detector output 433 includes soft data. As used herein, the phrase “soft data” is used in its broadest sense to mean reliability data with each instance of the reliability data indicating a likelihood that a corresponding bit position or group of bit positions has been correctly detected. In some embodiments of the present invention, the soft data or reliability data is log likelihood ratio data as is known in the art. Detector output 433 is provided to a local interleaver circuit 442. Local interleaver circuit 442 is operable to shuffle sub-portions (i.e., local chunks) of the data set included as detected output and provides an interleaved codeword 446 that is stored to central memory circuit 450. Interleaver circuit 442 may be any circuit known in the art that is capable of shuffling data sets to yield a re-arranged data set. Interleaved codeword 446 is stored to central memory circuit 450.

Once data decoding circuit 470 is available, a previously stored interleaved codeword 446 is accessed from central memory circuit 450 as a stored codeword 486 and globally interleaved by a global interleaver/de-interleaver circuit 484. Global interleaver/de-interleaver circuit 484 may be any circuit known in the art that is capable of globally rearranging codewords. Global interleaver/De-interleaver circuit 484 provides a decoder input 452 into data decoding circuit 470. Decoder output 452 may encoded similar to that discussed above in relation data encoder circuit 330 of FIG. 3. In some embodiments of the present invention, the data decode algorithm is a low density parity check algorithm as are known in the art. Based upon the disclosure provided herein, one of ordinary skill in the art will recognize other decode algorithms that may be used in relation to different embodiments of the present invention. Data decoding circuit 470 applies a data decode algorithm to decoder input 452 to yield a decoded output 471. In cases where another local iteration (i.e., another pass trough data decoding circuit 470) is desired, data decoding circuit 470 re-applies the data decode algorithm to decoder input 452 guided by decoded output 471. This continues until either a maximum number of local iterations is exceeded or decoded output 471 converges (i.e., completion of standard processing).

Where decoded output 471 fails to converge (i.e., fails to yield the originally written data set) and a number of local iterations through data decoding circuit 470 exceeds a threshold, the resulting decoded output is provided as a decoded output 454 back to central memory circuit 450 where it is stored awaiting another global iteration through a data detector circuit included in data detector circuit 430. Prior to storage of decoded output 454 to central memory circuit 450, decoded output 454 is globally de-interleaved to yield a globally de-interleaved output 488 that is stored to central memory circuit 450. The global de-interleaving reverses the global interleaving earlier applied to stored codeword 486 to yield decoder input 452. When a data detector circuit included in data detector circuit 430 becomes available, a previously stored de-interleaved output 488 is accessed from central memory circuit 450 and locally de-interleaved by a de-interleaver circuit 444. De-interleaver circuit 444 re-arranges decoder output 448 to reverse the shuffling originally performed by interleaver circuit 442. A resulting de-interleaved output 497 is provided to data detector circuit 430 where it is used to guide subsequent detection of a corresponding data set previously received as equalized output 425.

Alternatively, where the decoded output converges (i.e., yields the originally written data set), the resulting decoded output is provided as an output codeword 472 to a de-interleaver circuit 480 that rearranges the data to reverse both the global and local interleaving applied to the data to yield a de-interleaved output 482. De-interleaved output 482 is provided to a hard decision buffer circuit 428 buffers de-interleaved output 482 as it is transferred to the requesting host as a hard decision output 429. Of note, hard decision output 429 is the original user data included in decoded output 471 without the encoding information also included in decoded output 471. Hard decision output 429 is provided as refresh data to a data write circuit (e.g., refresh data 362 provided to data write circuit 300).

In addition, equalizer output 425 is provided to a refresh need detection circuit 490. Refresh need detection circuit 490 may be any circuit or system known in the art that is capable of determining that corruption of a recently read data set has reached a point where a refresh would be advisable to avoid the potential loss of data. As an example, refresh need detection circuit 490 may be an adjacent track interference detection circuit such as that disclosed in U.S. patent application Ser. No. 13/963,589 entitled “Data Processing System with Adjacent Track Interference Metric”, and filed Aug. 9, 2013 by Eui Seok Hwang et al. The entirety of the aforementioned application is incorporated herein by reference for all purposes. Based upon the disclosure provided herein, one of ordinary skill in the art will recognize a variety of detection circuits that may be used in relation to different embodiments of the present invention. Where refresh need detection circuit 490 determines a need to refresh the currently read data, an interim refresh signal 492 is asserted.

Interim refresh signal 492 is provided to a refresh selection circuit 494 along with a re-write signal 498. Re-write signal 498 is a host assertable signal that is asserted to cause a refresh of data. Refresh selection circuit 494 causes a refresh select signal 496 to be asserted whenever either re-write signal 498 or interim refresh signal 492 is asserted. Refresh select signal 496 is provided as a refresh select input to a data write circuit (e.g., refresh select 364 provided to data write circuit 300).

Turning to FIG. 5, a flow diagram 500 shows a method for data processing that includes selectable data re-writing in accordance with some embodiments of the present invention. Following flow diagram 500, it is determined whether a write request is received (block 505). Such a write request is received from a host device and includes a user data set and an address. The intent of the write request is to provide data that is to be written to a location corresponding to the received address on a storage medium. Where a write request is received (block 505), the received user data is encoded to yield an encoded output (block 510). The encoding applied may be, for example a low density parity check encoding as is known in the art. Based upon the disclosure provided herein, one of ordinary skill in the art will recognize a variety of encoding algorithms that may be used in relation to different embodiments of the present invention.

A physical address is generated based upon the received write address (block 515). The physical address represents a physical location on the storage medium. In some cases, an updatable table of received write addresses to physical addresses may be used to generate the physical address. Based upon the disclosure provided herein, one of ordinary skill in the art will recognize a variety of write address to physical address conversion approaches that may be used in relation to various embodiments of the present invention. The encoded data is then written to the storage medium at a location indicated by the physical address (block 520).

Alternatively, where the write request is not received (block 505), it is determined whether a request for read data is received (block 525). Such a read request is received from a host device and includes an address from which data is to be read. The intent of the read request is to access data from a location corresponding to the received address from a storage medium. A physical address is generated based upon the received read address (block 530). The physical address represents a physical location on the storage medium. In some cases, an updatable table of received write addresses to physical addresses may be used to generate the physical address. Based upon the disclosure provided herein, one of ordinary skill in the art will recognize a variety of write address to physical address conversion approaches that may be used in relation to various embodiments of the present invention.

Encoded data is accessed from the storage medium at a location indicated by the physical address (block 535). The encoded data includes an original user data set along with various encoding information. The accessed encoded data is converted to a digital data set (block 540). This may be done, for example, though use of analog to digital conversion circuitry.

A data processing algorithm is applied to the digital data set to yield the originally encoded data set (block 545). The data processing system includes, among other things, a data decoder circuit operable to reverse the encoding applied when the user data was originally stored to the storage medium. The resulting decoded output includes a combination of the original user data along with the various encoding information. The encoding information is stripped from the original user data to leave the original user data (block 550), and the resulting original user data is provided in response to the read request (block 555).

In addition, it is determined based upon the digital data set whether a data refresh is desired (block 560). This determination may be made, for example, based upon any problems encountered in applying the data processing algorithm of block 545, a time period since the data was last written, a number of accesses of the data since it was last written, inter-cell interference, or adjacent track interference. Based upon the disclosure provided herein, one of ordinary skill in the art will recognize that a variety of basis that may be used to cause a refresh in accordance with various embodiments of the present invention.

It is determined whether a data refresh or re-write is to be done (block 565). A refresh is determined as discussed in block 560, whereas a data re-write (technically a refresh) is determined when an external re-write signal is asserted. Assertion of the external re-write signal may be done when, for example, a defragmentation or garbage collection action is to be performed. Where a data refresh or re-write is to be done (block 565), a new physical address for the received read address is generated (block 570), and the originally encoded data from block 545 is written back to the storage medium at a location corresponding to the newly generated physical address (block 575). The new physical address may be the same as the old physical address in which case the data is re-written to the same location from which it was derived. In other cases, the new physical address is different from the old physical address in which case the data is re-written to a different location from which it was derived.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the invention provides novel systems, devices, methods and arrangements for data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A data storage system, the data storage system comprising:
a data processing circuit operable to:
receive a pre-processed encoded data set derived from a location on a storage medium;
apply a data processing algorithm to the pre-processed encoded data set to recover the original encoded data set, wherein the original encoded data set includes user data and encoding information;
provide the user data to a requesting device; and
a data write circuit operable to re-write the recovered original encoded data set to the storage medium.

2. The data storage system of claim 1, wherein the data write circuit further comprises:
a data encoding circuit operable to encode the user data to yield the original encoded data set; and
wherein the data write circuit is further operable to initially write the original encoded data set to the storage medium.

3. The data storage system of claim 2, wherein the data encoding circuit applies a low density parity check encoding algorithm.

4. The data storage system of claim 2, wherein the data processing circuit further comprises:
a refresh determination circuit operable to determine that a refresh of the pre-processed encoded data is warranted; and
wherein the data write circuit further includes:
a selector circuit operable to select the recovered original encoded data set provided from the data processing circuit as a write data output when it is determined that a refresh of the pre-processed encoded data is warranted.

5. The data storage system of claim 4, wherein the refresh determination circuit is operable to determine that a refresh of the pre-processed encoded data is warranted based upon a condition, and wherein the condition is selected from a group consisting of: exceeding a defined number of reads of the pre-processed encoded data since a last write of the pre-processed encoded data; exceeding a defined time period since the last write of the pre-processed encoded data; exceeding a defined level of inter-cell interference evident in the pre-processed encoded data; exceeding a defined level of adjacent track interference evident in the pre-processed encoded data; and exceeding a number of iterations of a data decoding algorithm required to yield the original encoded data set.

6. The data storage system of claim 4, wherein upon determination that a refresh of the pre-processed encoded data is warranted, data encoding circuit does not re-encode the user data to yield the original encoded data set.

7. The data storage system of claim 1, wherein the data processing algorithm includes a low density parity check decoding algorithm.

8. The data storage system of claim 1, wherein the storage system further comprises:
the storage medium, wherein the storage medium is selected from a group consisting of: a solid state storage medium, a magnetic storage medium, and an optical storage medium.

9. The data storage system of claim 1, wherein the data storage system is implemented as part of an integrated circuit.

10. A method for data refresh in a storage device, the method comprising:
writing an original encoded data set to a storage medium, wherein the original encoded data set includes user data and encoding information;
accessing a pre-processed encoded data set from a storage medium;
applying a data decoding algorithm to the pre-processed encoded data set to recover the original encoded data set;
providing the user data to a requesting device; and
re-writing the recovered original encoded data set to the storage medium.

11. The method of claim 10, the method further comprising:
encoding the user data to yield the original encoded data set.

12. The method of claim 11, wherein encoding the user data set includes applying a low density parity check encoding algorithm to the user data.

13. The method of claim 11, the method further comprising:
determining that a refresh of the pre-processed encoded data is warranted; and
selecting the recovered original encoded data set as a write data output when it is determined that a refresh of the pre-processed encoded data is warranted.

14. The method of claim 13, wherein determining that a refresh of the pre-processed encoded data is warranted is based upon a condition, and wherein the condition is selected from a group consisting of: exceeding a defined number of reads of the pre-processed encoded data since a last write of the pre-processed encoded data; exceeding a defined time period since the last write of the pre-processed encoded data; exceeding a defined level of inter-cell interference evident in the pre-processed encoded data; exceeding a defined level of adjacent track interference evident in the pre-processed encoded data; and exceeding a number of iterations of a data decoding algorithm required to yield the original encoded data set.

15. The method of claim 13, wherein upon determination that a refresh of the pre-processed encoded data is warranted, re-encoding of the user data to yield the original encoded data set.

16. The method of claim 10, wherein the data decoding algorithm includes a low density parity check decoding algorithm.

17. The method of claim 10, wherein the storage medium is selected from a group consisting of: a solid state storage medium, a magnetic storage medium, and an optical storage medium.

18. A storage device, the storage device comprising:
a data encoding circuit operable to encode a user data set to yield an original encoded data set, wherein the original encoded data set includes the user data set and encoding information;
a storage medium;
a data write circuit operable to write the original encoded data set to the storage medium;
a data processing circuit operable to:
receive a pre-processed encoded data set corresponding to the original encoded data set;
apply a data decoding algorithm to the pre-processed encoded data set to recover the original encoded data set;
provide the user data to a requesting device; and
wherein the data write circuit operable to re-write the recovered original encoded data set to the storage medium.

19. The storage device of claim 18, wherein the storage medium is selected from a group consisting of: a solid state storage medium, a magnetic storage medium, and an optical storage medium.

20. The storage device of claim 18, wherein the data processing circuit further comprises:
a refresh determination circuit operable to determine that a refresh of the pre-processed encoded data is warranted; and
wherein the data write circuit further includes:
a selector circuit operable to select the recovered original encoded data set provided from the data processing circuit as a write data output when it is determined that a refresh of the pre-processed encoded data is warranted.
